(19) United States
(12) Patent Application Publication
(10) Pub. No.: US 2014/0042874 A1
(43) Pub. Date: Feb. 13, 2014

(54) PIEZOELECTRIC VIBRATING PIECE AND PIEZOELECTRIC DEVICE

(71) Applicant: Nihon Dempa Kogyo Co., Ltd., Tokyo (JP)

(72) Inventors: TAKEHIRO TAKAHASHI, Saitama (JP); SHUICHI MIZUSAWA, Saitama (JP); TAKUMI ARIJI, Saitama (JP)

(73) Assignee: NIHON DEMPA KOGYO CO., LTD., Tokyo (JP)

(21) Appl. No.: 13/948,158

(22) Filed: Jul. 22, 2013

(30) Foreign Application Priority Data
Aug. 10, 2012 (JP) 2012-178523

(51) Int. Cl. H01L 41/107

(52) U.S. Cl. CPC H01L 41/107
USPC 310/351

(57) ABSTRACT

A piezoelectric vibrating piece includes a vibrator, a framing portion, a connecting portion, and an extraction electrode. The vibrator includes excitation electrodes formed on both principal surfaces. The framing portion includes an inner peripheral side facing the vibrator and an outer peripheral side on an opposite side of the inner peripheral side. The framing portion has a predetermined width from the inner peripheral side to the outer peripheral side. The connecting portion connects the vibrator and the framing portion. The extraction electrode is extracted from the excitation electrode to the framing portion via the connecting portion. The extraction electrode contacts the inner peripheral side and the outer peripheral side of the framing portion. The extraction electrode includes an end side that connects the inner peripheral side and the outer peripheral side of the extraction electrode. All of the end side is longer than the predetermined width.

### CROSS REFERENCE TO RELATED APPLICATIONS

This application claims the priority benefit of Japan application serial no. 2012-178523, filed on Aug. 10, 2012. The entirety of the above-mentioned patent application is hereby incorporated by reference herein and made a part of this specification.

### TECHNICAL FIELD

This disclosure relates to a piezoelectric vibrating piece where a framing portion is formed, and a piezoelectric device.

### DESCRIPTION OF THE RELATED ART

A piezoelectric vibrating piece that includes a vibrator vibrating at a predetermined vibration frequency, a framing portion surrounding the vibrator, and a connecting portion connecting the vibrator and the framing portion is known. In this piezoelectric vibrating piece, a base plate and a lid plate are respectively bonded on one principal surface and the other principal surface of the framing portion via a bonding material to form a piezoelectric device. A pair of excitation electrodes is formed on both principal surfaces of the vibrator of the piezoelectric vibrating piece. Extraction electrodes are extracted from the respective excitation electrodes to the framing portion.

For example, Japanese Unexamined Patent Application Publication No. 2010-200118 (hereinafter referred to as Patent Literature 1) discloses a piezoelectric vibrating piece where an extraction electrode is formed. The extraction electrode is extracted from an excitation electrode to a framing portion. The extraction electrode, which is extracted to the framing portion, extends from one side of the framing portion around the outer side of a vibrator to the other side of the framing portion. The extraction electrode formed at the framing portion is formed across the entire width of the framing portion.

However, in the case where the piezoelectric vibrating piece described in Patent Literature 1 is used for the piezoelectric device, there is a problem as follows. An end side of the extraction electrode, which is formed at the framing portion, is eroded due to corrosion and leads to a connection between external environment and an inner side of the piezoelectric device. This causes a cavity of the piezoelectric device to be leaked.

A need thus exists for a piezoelectric vibrating piece and a piezoelectric device which are not susceptible to the drawback mentioned above.

### SUMMARY

A piezoelectric vibrating piece according to a first aspect includes a vibrator, a framing portion, a connecting portion, and an extraction electrode. The vibrator has a rectangular shape with a short side and a long side. The vibrator includes excitation electrodes formed on both principal surfaces. The vibrator vibrates at a predetermined vibration frequency. The framing portion surrounds the vibrator. The framing portion includes an inner peripheral side facing the vibrator and an outer peripheral side on an opposite side of the inner peripheral side. The framing portion has a predetermined width from the inner peripheral side to the outer peripheral side. The connecting portion connects the vibrator and the framing portion. The extraction electrode extracted from the excitation electrode to the framing portion via the connecting portion. The extraction electrode contacts the inner peripheral side and the outer peripheral side of the framing portion. The extraction electrode includes an end side that connects the inner peripheral side and the outer peripheral side of the extraction electrode. All of the end sides are longer than the predetermined width.

### BRIEF DESCRIPTION OF THE DRAWINGS

The foregoing and additional features and characteristics of this disclosure will become more apparent from the following detailed description considered with reference to the accompanying drawings, wherein:

FIG. 1 is an exploded perspective view of a piezoelectric device 100;

FIG. 2A is a cross-sectional view taken along the line A-A of FIG. 1;

FIG. 2B is an enlarged view of a dotted line 161 of FIG. 2A;

FIG. 3A is a plan view of a piezoelectric vibrating piece 130;

FIG. 3B is a cross-sectional view of the piezoelectric vibrating piece 130 on the surface at the −Y′-axis side viewed from the +Y′-axis side;

FIG. 4 is a plan view of a piezoelectric wafer W130;

FIG. 5A is a plan view of a piezoelectric vibrating piece 230;

FIG. 5B is a plan view of the piezoelectric vibrating piece 230 on the surface at the −Y′-axis side viewed from the surface at the +Y′-axis side;

FIG. 6A is a plan view of a piezoelectric vibrating piece 330;

FIG. 6B is a plan view of the piezoelectric vibrating piece 330 on the surface at the −Y′-axis side viewed from the surface at the +Y′-axis side;

FIG. 7A is a plan view of a piezoelectric vibrating piece 430; and

FIG. 7B is a plan view of the piezoelectric vibrating piece 430 on the surface at the −Y′-axis side viewed from the surface at the +Y′-axis side.

### DETAILED DESCRIPTION

The preferred embodiments of this disclosure will be described with reference to the attached drawings. It will be understood that the scope of the disclosure is not limited to the described embodiments, unless otherwise stated.

### Constitution Of A Piezoelectric Device 100 According To A First Embodiment

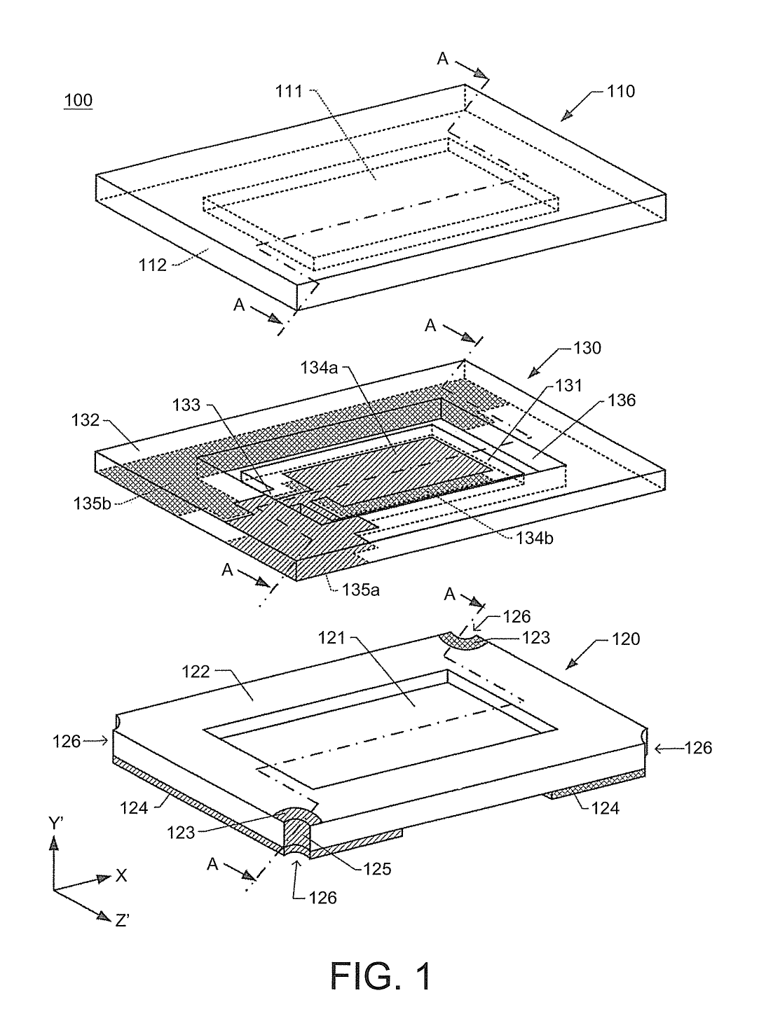

FIG. 1 is an exploded perspective view of the piezoelectric device 100. The piezoelectric device 100 includes a lid plate 110, a base plate 120, and a piezoelectric vibrating piece 130. For example, an AT-cut quartz-crystal vibrating piece is used for the piezoelectric vibrating piece 130, the lid plate 110, and the base plate 120. The AT-cut quartz-crystal vibrating piece has a principal surface (in the Y-Z plane) that is tilted by 35° 15′ about the Y-axis of crystallographic axes (XYZ) in the direction from the Z-axis to the Y-axis around the X-axis. In the following description, the new axes tilted with reference to the axis directions of the AT-cut quartz-crystal vibrating piece are denoted as the Y′-axis and the Z′-axis. This disclosure defines the long side direction of the piezoelectric device 100 as the X-axis direction, the height direction of the piezoelectric device 100 as the Y′-axis direction, and the direction perpendicular to the X and Y′-axis directions as the Z′-axis direction.

The piezoelectric vibrating piece 130 includes a vibrator 131 vibrating at a predetermined vibration frequency, a framing portion 132 surrounding the vibrator 131, and a connecting portion 133 connecting the vibrator 131 and the framing portion 132. An excitation electrode 134a and an excitation electrode 134b are formed on the surface at the +Y′-axis side and on the surface at the −Y′-axis side of the vibrator 131, respectively. An extraction electrode 135a and an extraction electrode 135b are respectively extracted from the excitation electrode 134a and the excitation electrode 134b to the −X-axis side at the +Z′-axis side and the +X-axis side at the −Z′-axis side on the surface at the −Y′-axis side of the framing portion 132 via the connecting portion 133. A through groove 136 is formed between the vibrator 131 and the framing portion 132. The through groove 136 passes through the piezoelectric vibrating piece 130 in the Y′-axis direction.

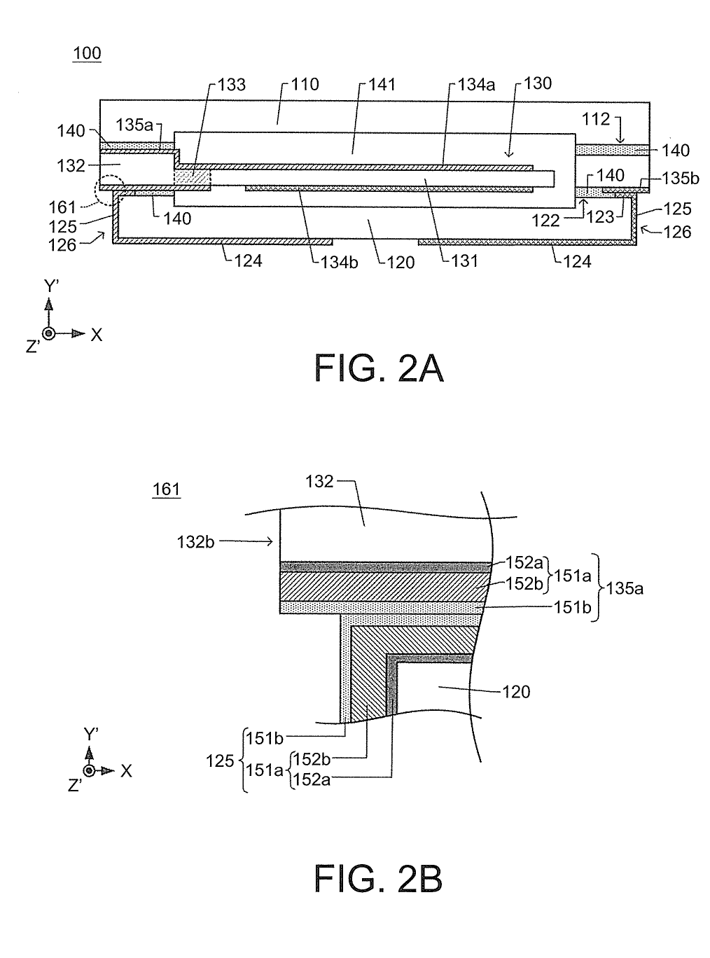

The base plate 120 includes a depressed portion 121 depressed at the −Y′-axis side, a bonding surface 122, and connecting electrodes 123 on the surface at the +Y′-axis side. The bonding surface 122 surrounds the depressed portion 121. The connecting electrodes 123 are disposed at the corner of the +X-axis side and the −Z′-axis side and at the corner of the −X-axis side and the +Z′-axis side of the bonding surface 122. The bonding surface 122 is to be bonded on the surface at the −Y′-axis side of the framing portion 132 of the piezoelectric vibrating piece 130 via a bonding material 140 (see FIG. 2A). Additionally, a pair of mounting terminals 124 is formed on the surface at the −Y′-axis side of the base plate 120. Furthermore, castellations 126 are formed at four corners of the side surfaces of the base plate 120. Castellation electrodes 125 are formed at the side surface at the +X-axis side at the −Z′-axis side and the side surface at the −X-axis side at the +Z′-axis side of the castellations 126. The castellation electrode 125 electrically connects the connecting electrode 123 and the mounting terminal 124. The connecting electrode 123, which is formed at the corner at the −X-axis side and the +Z′-axis side, electrically connects to the extraction electrode 135a extracted to the corner at the −X-axis side and the +Z′-axis side on the surface at the −Y′-axis side of the piezoelectric vibrating piece 130. The connecting electrode 123, which is formed at the corner at the +X-axis side and the −Z′-axis side, electrically connects to the extraction electrode 135b extracted to the corner at the +X-axis side and the −Z′-axis side on the surface at the −Y′-axis side of the piezoelectric vibrating piece 130.

The lid plate 110 includes a depressed portion 111 and a bonding surface 112 on the surface at the −Y′-axis side. The bonding surface 112 surrounds the depressed portion 111. The bonding surface 112 is to be bonded on the surface at the +Y′-axis side of the framing portion 132 of the piezoelectric vibrating piece 130 via the bonding material 140 (see FIG. 2A).

FIG. 2A is a cross-sectional view taken along the line A-A of FIG. 1. The piezoelectric device 100 includes the lid plate 110 at the +Y′-axis side and the base plate 120 at the −Y′-axis side of the piezoelectric vibrating piece 130. The piezoelectric device 100 includes a cavity 141 formed by the depressed portion 111 of the lid plate 110 and the depressed portion 121 of the base plate 120. The vibrator 131 of the piezoelectric vibrating piece 130 is disposed in the cavity 141. The cavity 141 is sealed by forming the non-conductive bonding materials 140 between the bonding surface 112 of the lid plate 110 and the surface at the +Y′-axis side of the framing portion 132, and between the bonding surface 122 of the base plate 120 and the surface at the −Y′-axis side of the framing portion 132. The extraction electrode 135a and the extraction electrode 135b, which are formed at the framing portion 132, electrically connect to the connecting electrode 123 formed at the base plate 120. This electrically connects the excitation electrode 134a and the excitation electrode 134b to a pair of mounting terminals 124.

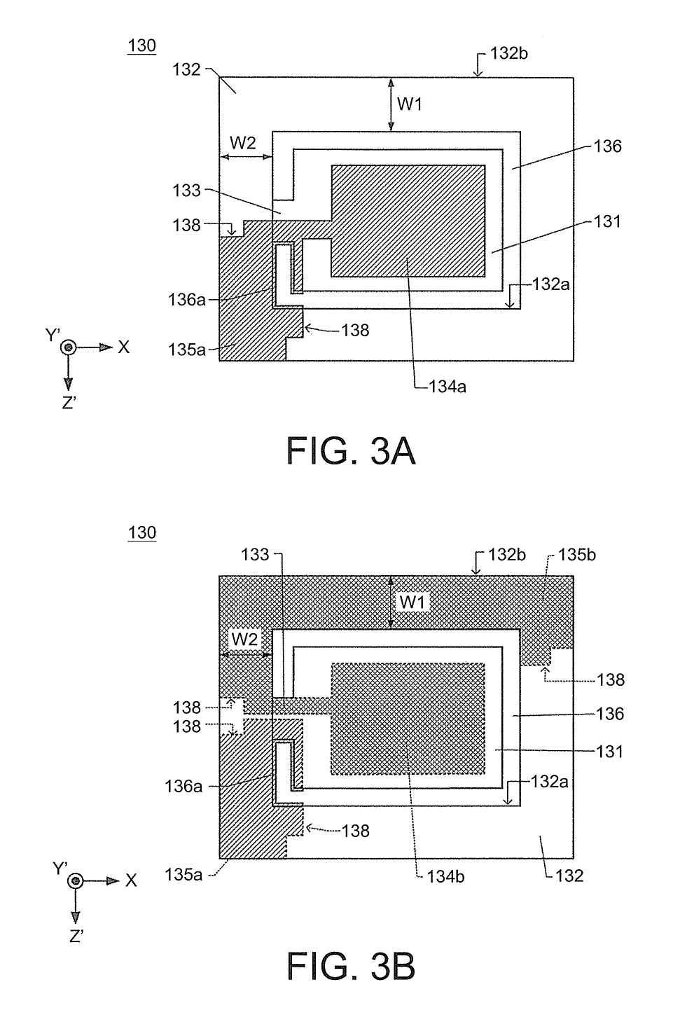

FIG. 2B is an enlarged view of a dotted line 161 of FIG. 2A. Each electrode formed in the piezoelectric vibrating piece 130 and at the base plate 120 includes a first metal layer 151a and a second metal layer 151b. The first metal layer 151a is formed on the surface of a quartz-crystal material constituting the piezoelectric vibrating piece 130 and the base plate 120. The second metal layer 151b is formed on the surface of the first metal layer 151a. The first metal layer 151a has a role in good adhesion for each electrode to the quartz-crystal material constituting the piezoelectric vibrating piece 130 or similar member. The second metal layer 151b has a role in protection for each electrode. The first metal layer 151a, which is formed in the piezoelectric device 100, for example, is made of a chromium (Cr) layer 152a and a nickel tungsten (NiW) layer 152b. The chromium (Cr) layer 152a is formed on the surface of the quartz-crystal material. The nickel tungsten (NiW) layer 152b is formed on the surface of the chromium (Cr) layer 152a. Chromium (Cr) provides good adhesion to the quartz-crystal material. Hence, each electrode and the quartz-crystal material are strongly adhered together. This allows each electrode to be fixed to the quartz-crystal material. Additionally, nickel tungsten (NiW) prevents the weakness of the bonding between the quartz-crystal material and the chromium (Cr) layer 152a where chromium (Cr) diffuses into the second metal layer 151b. The second metal layer 151b, for example, can be made of gold (Au). Gold (Au) is chemically stable such that gold (Au) is capable of protecting each electrode from corrosion or similar problem. As illustrated in FIG. 2B, the extraction electrode 135a and the extraction electrode 135b formed in the piezoelectric vibrating piece 130 are formed as follows. The first metal layer 151a and the second metal layer 151b of the extraction electrode 135a and the extraction electrode 135b contacting an outer peripheral side 132b (see FIG. 3A) of the framing portion 132 in the piezoelectric vibrating piece 130 are formed so as to contact the external environment of the piezoelectric device 100.

FIG. 3A is a plan view of the piezoelectric vibrating piece 130. The vibrator 131 of the piezoelectric vibrating piece 130 has a rectangular shape with a long side parallel to the X-axis and a short side parallel to the Z′-axis. The framing portion 132 includes an inner peripheral side 132a facing the vibrator 131 and the outer peripheral side 132b on the opposite side of the inner peripheral side 132a. The connecting portion 133 connects a center of the side at the −X-axis side of the vibrator 131 and the center of the inner peripheral side 132a at the −X-axis side of the framing portion 132. In the case where the piezoelectric vibrating piece 130 is formed as a part of the piezoelectric device 100, the outer peripheral side 132b contacts the external environment of the piezoelectric device 100. The extraction electrode 135a passes across the connecting portion 133 and is extracted from the excitation electrode 134a to the −X-axis side and the +Z′-axis side on the surface at the +Y′-axis side of the framing portion 132. The excitation electrode 134a is formed on the surface at the +Y′-axis side of the vibrator 131. The extraction electrode 135a is extracted to the surface at the −Y′-axis side via a side surface 136a at the −X-axis side and the +Z′-axis side of the through groove 136. The side surface 136a of the through groove 136 where the extraction electrode 135a is formed mainly includes the +Z′-axis side of the side at the −X-axis side of the vibrator 131, the +Z′-axis side of the connecting portion 133, and the −X-axis side and the +Z′-axis side of the inner peripheral side 132a of the framing portion 132.

Assume that the width in the Z′-axis direction of the framing portion 132 extending in the X-axis direction is a width W1. The framing portion 132 extending in the X-axis direction is disposed at the +Z′-axis side and the −Z′-axis side of the vibrator 131. Assume that the width in the X-axis direction of the framing portion 132 extending in the Z′-axis direction is a width W2. The framing portion 132 extending in the Z′-axis direction is disposed at the +X-axis side and the −X-axis side of the vibrator 131. In the piezoelectric vibrating piece 130, the sizes of the width W1 and the width W2 are equally formed. The extraction electrode 135a is formed across the full width of the framing portion 132. The extraction electrode 135a is formed on the surface at the +Y′-axis side of the framing portion 132. Hence, the extraction electrode 135a, which is formed on the surface at the +Y′-axis side of the framing portion 132, includes a side contacting the inner peripheral side 132a of the framing portion 132, a side contacting the outer peripheral side 132b of the framing portion 132, and an end side 138. The end side 138 does not contact the inner peripheral side 132a and the outer peripheral side 132b and connects the inner peripheral side 132a and the outer peripheral side 132b. The extraction electrode 135a is formed on the surface at the +Y′-axis side of the framing portion 132. Each end side 138 of the extraction electrode 135a is formed in an L shape to include a straight line extending in the X-axis direction and a straight line extending in the Z′-axis direction. Hence, the length of each end side 138 is formed longer compared with the width W1 and the width W2 of the framing portion 132.

FIG. 3B is a cross-sectional view of the piezoelectric vibrating piece 130 on the surface at the −Y′-axis side viewed from the +Y′-axis side. The excitation electrode 134b is formed on the surface at the −Y′-axis side of the vibrator 131. The extraction electrode 135b extends in the −X-axis direction and is extracted from the excitation electrode 134b to the +X-axis side and the −Z′-axis side on the surface at the −Y′-axis side of the framing portion 132 via the connecting portion 133. The extraction electrode 135a is extracted from the surface at the +Y′-axis side to the surface at the −Y′-axis side via the side surface 136a of the through groove 136. The extraction electrode 135a is further extracted to the corner at the −X-axis side and the +Z′-axis side of the framing portion 132 on the surface at the −Y′-axis side of the piezoelectric vibrating piece 130. The extraction electrode 135a and the extraction electrode 135b are formed at the −Y′-axis side of the framing portion 132. The extraction electrode 135a and the extraction electrode 135b are formed across the full width of the framing portion 132, similarly to the extraction electrode 135a formed on the surface at the +Y′-axis side of the framing portion 132. All of the end sides 138 are formed in an L shape.

As illustrated in FIG. 3A and FIG. 3B, in the piezoelectric vibrating piece 130, the extraction electrode 135a and the extraction electrode 135b formed at the framing portion 132 are formed across the full widths of the width W1 and the width W2 of the framing portion 132. Hence, in the piezoelectric vibrating piece 130, the increase of electrical resistance caused by the extraction electrode 135a and the extraction electrode 135b is suppressed. The increase of a crystal impedance (CI) value of the piezoelectric vibrating piece 130 is suppressed.

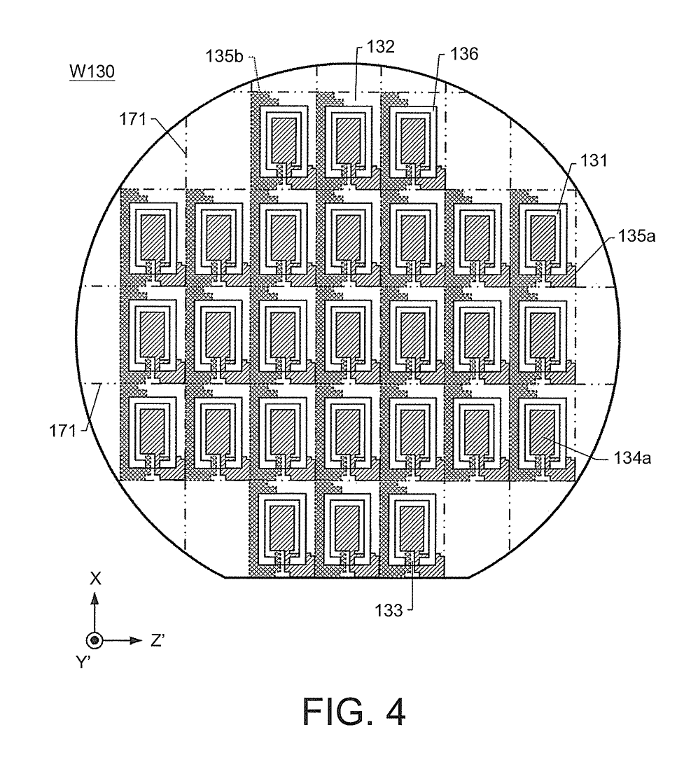

FIG. 4 is a plan view of a piezoelectric wafer W130. The method for forming the piezoelectric vibrating piece 130 will be described with reference to FIG. 4. A piezoelectric vibrating piece forms a large number of piezoelectric vibrating pieces on a piezoelectric wafer made of a piezoelectric material. This allows forming simultaneously a large number of piezoelectric vibrating pieces. FIG. 4 illustrates the piezoelectric wafer W130 where the plurality of piezoelectric vibrating pieces 130 is formed. The outline of the piezoelectric vibrating piece 130 is formed by etching the piezoelectric wafer W130. Furthermore, the excitation electrode 134a, the excitation electrode 134b, the extraction electrode 135a, and the extraction electrode 135b are formed by sputtering chromium (Cr), nickel tungsten (NiW), and gold (Au).

The piezoelectric wafer W130 illustrated in FIG. 4 includes the plurality of piezoelectric vibrating pieces 130 aligned in the X-axis direction and the Z′-axis direction. Additionally, FIG. 4 illustrates a scribe line 171 between each of the piezoelectric vibrating pieces 130 neighboring each other. The piezoelectric wafer W130 is diced along the scribe line 171. Thus, the piezoelectric vibrating pieces 130 are divided individually. The extraction electrode 135a and the extraction electrode 135b formed in the piezoelectric vibrating piece 130 are formed so as to overlap in this scribe line 171. This allows forming the extraction electrode 135a and the extraction electrode 135b across the full width of the framing portion 132. The outer peripheral side 132b of the framing portion 132 is formed by a trace diced by the scribe line 171. Hence, as illustrated in FIG. 2B, the first metal layer 151a and the second metal layer 151b of the extraction electrode 135a and the extraction electrode 135b are formed so as to contact the external environment of the piezoelectric device 100.

A piezoelectric device should be formed so that there is no characteristic deterioration. Hence, characteristic deterioration of the piezoelectric device is examined by performing a moisture resistance test, a salt spray test, or similar test. An electrode contacting this poor external environment corrodes and erodes. Especially, since the first metal layer 151a forming an electrode is susceptible to corrosion or similar, the first metal layer 151a exposed at the outer peripheral side 132b may pass along the end side 138 and reach the inner peripheral side 132a of the extraction electrodes 135a and 135b. Therefore, when corrosion of the electrode reaches the inner peripheral side 132a from the outer peripheral side 132b, sealing of the cavity 141 of the piezoelectric device 100 is dissolved.

The end side 138 of the piezoelectric vibrating piece 130 is formed in an L shape by the plurality of straight lines. Therefore, the length of the end side 138 is formed longer compared with the width W1 and the width W2 of the framing portion 132. Hence, although the first metal layer 151a contacting the external environment corrodes and erodes, the erosion hardly reaches the inner peripheral side 132a from the outer peripheral side 132b of the framing portion 132. This prevents the sealing of the cavity 141 of the piezoelectric device 100 from being dissolved.

### Second Embodiment

The end side of the extraction electrode can be formed in various shapes. A description will be given of the modifications of the piezoelectric vibrating piece where the end side is formed in various shapes. Like reference numerals designate corresponding or identical elements throughout the first embodiment and the second embodiment, and therefore such elements will not be further elaborated here.

### Constitution Of A Piezoelectric Vibrating Piece 230

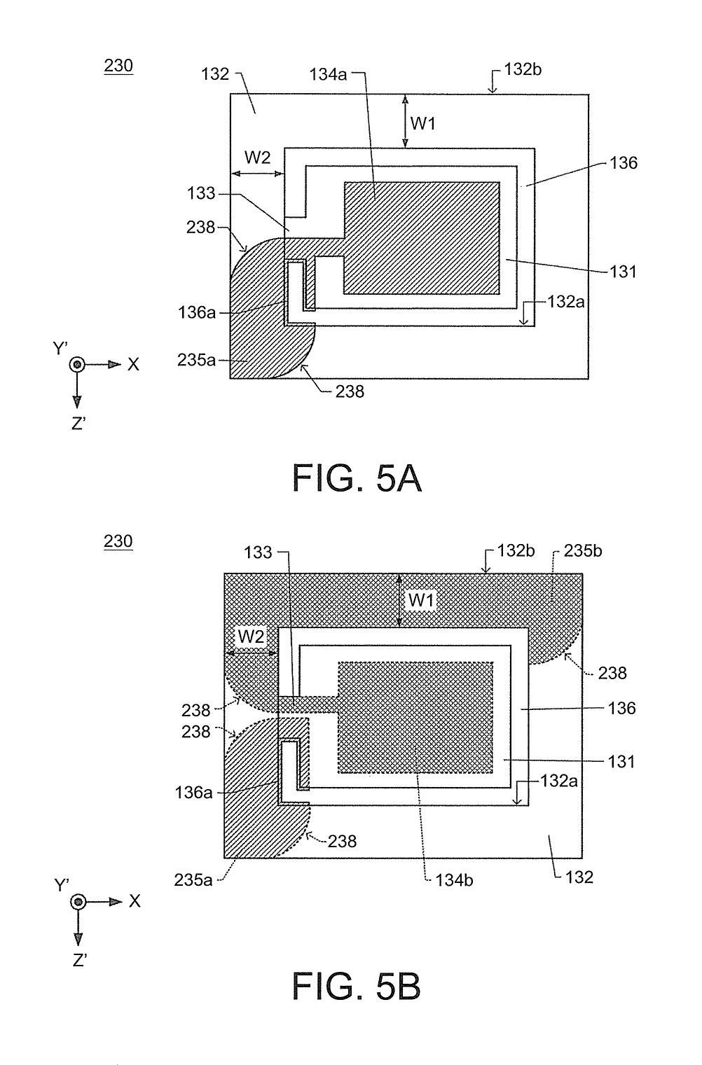

FIG. 5A is a plan view of a piezoelectric vibrating piece 230. The piezoelectric vibrating piece 230 includes the vibrator 131, the framing portion 132, and the connecting portion 133. The excitation electrode 134a is formed on the surface at the +Y′-axis side of the vibrator 131. An extraction electrode 235a is extracted from the excitation electrode 134a. The extraction electrode 235a extends in the −X-axis direction from the excitation electrode 134a. The extraction electrode 235a passes across the connecting portion 133 and is extracted to the −X-axis side and the +Z′-axis side of the framing portion 132. The extraction electrode 235a is extracted to the surface at the −Y′-axis side via the side surface 136a of the through groove 136. The extraction electrode 235a is formed across the full width of the framing portion 132. Hence, an end side 238 is formed in the extraction electrode 235a. The end side 238 is formed with a fan-shape curved line expanding to the outside of the extraction electrode 235a.

FIG. 5B is a plan view of the piezoelectric vibrating piece 230 on the surface at the −Y′-axis side viewed from the surface at the +Y′-axis side. The excitation electrode 134b is formed on the surface at the −Y′-axis side of the vibrator 131. An extraction electrode 235b is formed from the excitation electrode 134b to the corner at the +X-axis side and the −Z′-axis side of the framing portion 132 via the connecting portion 133. The extraction electrode 235a is extracted from the surface at the +Y′-axis side to the surface at the −Y′-axis side via the side surface 136a of the through groove 136. The extraction electrode 235a is formed to the corner at the −X-axis side and the +Z′-axis side of the framing portion 132. The extraction electrode 235a and the extraction electrode 235b, which are formed on the surface at the −Y′-axis side of the framing portion 132, are formed across the full width of the framing portion 132 and include the end side 238.

All of the end sides 238 formed in the piezoelectric vibrating piece 230 are formed with a fan-shape curved line expanding to the outside of the extraction electrode 235a or the extraction electrode 235b. Therefore, the length of the end side 238 is formed longer compared with the width W1 and the width W2 of the framing portion 132. Hence, even if the first metal layer 151a exposed to the outer peripheral side 132b corrodes, the erosion hardly reaches within the cavity 141. This prevents the sealing of the cavity 141 of the piezoelectric device 100 from being dissolved. In the piezoelectric vibrating piece 230, the end sides 238 adjacent to the connecting portion 133 are formed with a fan-shape curved line expanding to the outsides of the extraction electrodes 235a and 235b. Accordingly, this configuration is preferred because the width of the extraction electrodes 235a and 235b near the connecting portion 133 are not significantly narrowed.

### Constitution Of A Piezoelectric Vibrating Piece 330

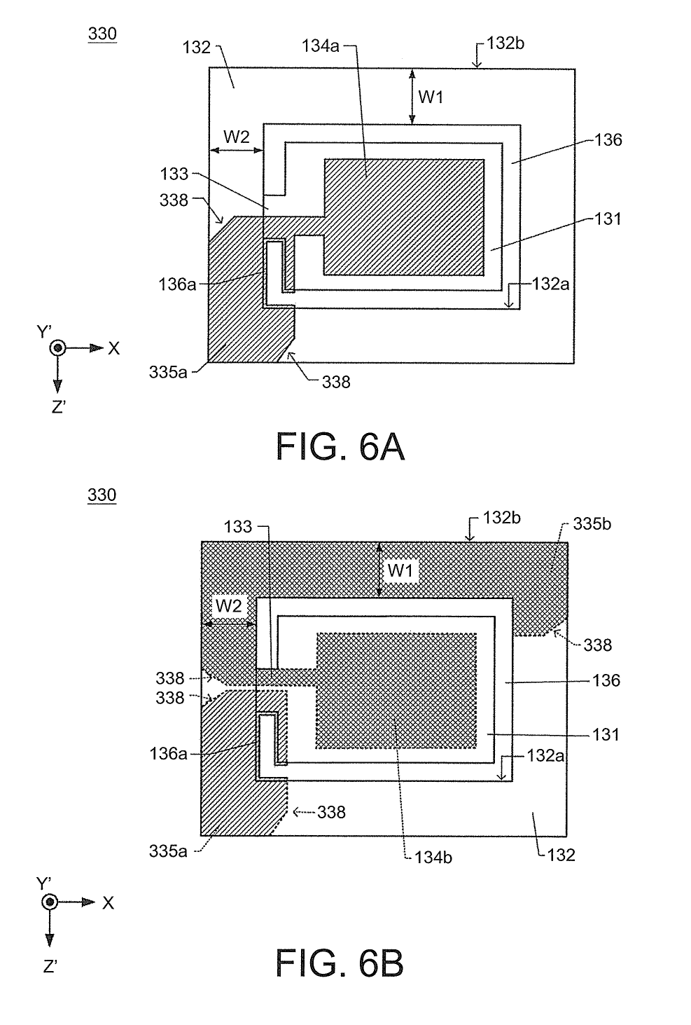

FIG. 6A is a plan view of a piezoelectric vibrating piece 330. The piezoelectric vibrating piece 330 includes the vibrator 131, the framing portion 132, and the connecting portion 133. The excitation electrode 134a is formed on the surface at the +Y′-axis side of the vibrator 131. An extraction electrode 335a is extracted from the excitation electrode 134a. The extraction electrode 335a extends in the −X-axis direction from the excitation electrode 134a. The extraction electrode 335a passes across the connecting portion 133 and is extracted to the −X-axis side and the +Z′-axis side of the framing portion 132. The extraction electrode 335a is extracted to the surface at the −Y′-axis side via the side surface 136a of the through groove 136. The extraction electrode 335a is formed across the full width of the framing portion 132. Hence, an end side 338 is formed in the extraction electrode 335a. The end side 338 is formed to include a straight line that is not parallel to the X-axis and the Z′-axis. That is, the straight line has an angle with respect to the X-axis and the Z′-axis.

FIG. 6B is a plan view of the piezoelectric vibrating piece 330 on the surface at the −Y′-axis side viewed from the surface at the +Y′-axis side. The excitation electrode 134b is formed on the surface at the −Y′-axis side of the vibrator 131. An extraction electrode 335b is formed from the excitation electrode 134b to the corner at the +X-axis side and the −Z′-axis side of the framing portion 132 via the connecting portion 133. The extraction electrode 335a is extracted from the surface at the +Y′-axis side to the surface at the −Y′-axis side via the side surface 136a of the through groove 136. The extraction electrode 335a is formed to the corner at the −X-axis side and the +Z′-axis side of the framing portion 132. The end side 338 is formed in the extraction electrode 335a and the extraction electrode 335b, which are formed on the surface at the −Y′-axis side of the framing portion 132.

In the piezoelectric vibrating piece 330, the end side 338 is formed to include the straight line that is not parallel to the X-axis and the Z′-axis. Therefore, the length of the end side 338 is formed longer compared with the width WI and the width W2 of the framing portion 132. Hence, even if the first metal layer 151a exposed to the outer peripheral side 132b corrodes, the erosion hardly reaches within the cavity 141. This prevents the sealing of the cavity 141 of the piezoelectric device 100 from being dissolved.

### Constitution Of A Piezoelectric Vibrating Piece 430

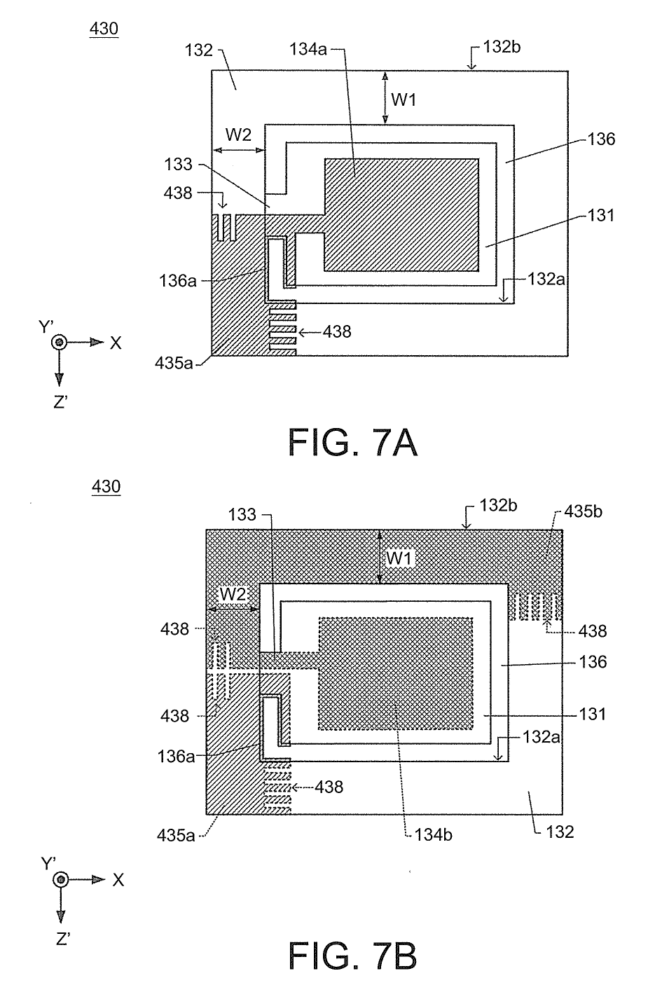

FIG. 7A is a plan view of a piezoelectric vibrating piece 430. The piezoelectric vibrating piece 430 includes the vibrator 131, the framing portion 132, and the connecting portion 133. The excitation electrode 134a is formed on the surface at the +Y′-axis side of the vibrator 131. An extraction electrode 435a is extracted from the excitation electrode 134a. The extraction electrode 435a extends in the −X-axis direction from the excitation electrode 134a. The extraction electrode 435a passes across the connecting portion 133 and is extracted to the −X-axis side and the +Z′-axis side of the framing portion 132. The extraction electrode 435a is extracted on the surface at the −Y′-axis side via the side surface 136a of the through groove 136. The extraction electrode 435a is formed across the full width of the framing portion 132. Hence, an end side 438 is formed in the extraction electrode 435a. The end side 438 is formed in a comb shape where a plurality of straight lines is connected. In the extraction electrode 435a, the end side 438 is not formed in a comb shape adjacent to the inner peripheral side 132a close to the connecting portion 133.

FIG. 7B is a plan view of the piezoelectric vibrating piece 430 on the surface at the −Y′-axis side viewed from the surface at the +Y′-axis side. The excitation electrode 134b is formed on the surface at the −Y′-axis side of the vibrator 131. An extraction electrode 435b is formed from the excitation electrode 134b to the corner at the +X-axis side and the −Z′-axis side on the surface at the −Y′-axis side of the framing portion 132 via the connecting portion 133. The extraction electrode 435a is extracted from the surface at the +Y′-axis side to the surface at the −Y′-axis side via the side surface 136a of the through groove 136. The extraction electrode 435a is formed to the corner at the −X-axis side and the +Z′-axis side of the framing portion 132. The end side 438 is formed in the extraction electrode 435a and the extraction electrode 435b formed on the surface at the −Y′-axis side of the framing portion 132. In the extraction electrode 435a and the extraction electrode 435b, the end side 438 is not formed in a comb shape adjacent to the inner peripheral side 132a close to the connecting portion 133.

In the piezoelectric vibrating piece 430, the end side 438 is formed in a comb shape. Therefore, the length of the end side 438 is formed longer compared with the width W1 and the width W2 of the framing portion 132. Hence, even if the first metal layer 151a exposed to the outer peripheral side 132b corrodes, the erosion hardly reaches within the cavity 141. This prevents the sealing of the cavity 141 of the piezoelectric device 100 from being dissolved. The end side 438 is not formed in a comb shape adjacent to the inner peripheral side 132a close to the connecting portion 133. Accordingly, the widths of the extraction electrode 435a and the extraction electrode 435b are substantially decreased. This prevents a large increase in the electrical resistances of the extraction electrode 435a and the extraction electrode 435b.

Representative embodiments are described in detail above; however, as will be evident to those skilled in the relevant art, this disclosure may be changed or modified in various ways within its technical scope.

For example, the first metal layer 151a includes the chromium (Cr) layer 152a and the nickel tungsten (NiW) layer 152b. However, the first metal layer 151a may be made of the chromium (Cr) layer 152a alone. The first metal layer 151a may be made as the chromium (Cr) layer 152a and a nickel (Ni) layer by using the nickel (Ni) layer instead of the nickel tungsten (NiW) layer 152b. At this time, for example, the extraction electrode 135a includes the first metal layer 151a and the second metal layer 151b. The first metal layer 151a is made of the chromium (Cr) layer 152a and the nickel (Ni) layer, which is formed on the surface of the chromium (Cr) layer 152a. The second metal layer 151b is formed as a gold (Au) layer on the surface of the nickel (Ni) layer.

The above-described embodiments disclose a case where the piezoelectric vibrating piece is an AT-cut quartz-crystal vibrating piece. A BT-cut quartz-crystal vibrating piece or similar member that similarly vibrates in the thickness-shear mode is similarly applicable. Further, the piezoelectric vibrating piece is basically applicable to a piezoelectric material that includes not only a quartz-crystal material but also lithium tantalate, lithium niobate, and piezoelectric ceramics.

A piezoelectric vibrating piece according to a first aspect includes a vibrator, a framing portion, a connecting portion, and an extraction electrode. The vibrator has a rectangular shape with a short side and a long side. The vibrator includes excitation electrodes formed on both principal surfaces. The vibrator vibrates at a predetermined vibration frequency. The framing portion surrounds the vibrator. The framing portion includes an inner peripheral side facing the vibrator and an outer peripheral side on an opposite side of the inner peripheral side. The framing portion has a predetermined width which intersects perpendicularly from the inner peripheral side to the outer peripheral side. The connecting portion connects the vibrator and the framing portion. The extraction electrode extracted from the excitation electrode to the framing portion via the connecting portion. The extraction electrode contacts the inner peripheral side and the outer peripheral side of the framing portion. The extraction electrode includes an end side that connects the inner peripheral side and the outer peripheral side of the extraction electrode. All of the end side is longer than the predetermined width.

In the first aspect of the disclosure, the piezoelectric vibrating piece according to a second aspect is configured as follows. The end side includes at least one of a plurality of straight lines, a curved line, and a straight line having an angle with respect to the long side and the short side.

In the second aspect of the disclosure, the piezoelectric vibrating piece according to a third aspect is configured as follows. The end side is formed in an L shape, a fan shape, a comb shape, or a shape in combination of the L shape, the fan shape, and the comb shape shapes.

In the first aspect to the third aspect of the disclosure, the piezoelectric vibrating piece according to a fourth aspect is configured as follows. The extraction electrode includes a first metal layer and a second metal layer formed on a surface of the first metal layer. The first metal layer is made of chromium (Cr), chromium (Cr) and nickel (Ni), or chromium (Cr) and nickel tungsten (NiW).

A piezoelectric device according to a fifth aspect includes the piezoelectric vibrating piece, a base plate, a lid plate, and a non-conductive bonding material.

The piezoelectric vibrating piece is according to the first aspect to the fourth aspect. The base plate is bonded on one principal surface of the framing portion. The lid plate is bonded on another principal surface of the framing portion to seal the vibrator. The non-conductive bonding material bonds the piezoelectric vibrating piece and the base plate and bonds the piezoelectric vibrating piece and the lid plate. The end side contacts the bonding material as viewed from the outer peripheral side.

With the piezoelectric vibrating piece and the piezoelectric device according to the embodiments, a leakage in a cavity can be reduced.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a vibrator that has a rectangular shape with a short side and a long side, the vibrator including excitation electrodes formed on both principal surfaces, the vibrator vibrating at a predetermined vibration frequency;
a framing portion that surrounds the vibrator, the framing portion including an inner peripheral side facing the vibrator and an outer peripheral side on an opposite side of the inner peripheral side, the framing portion having a predetermined width from the inner peripheral side to the outer peripheral side;
a connecting portion that connects the vibrator and the framing portion; and
an extraction electrode extracted from the excitation electrode to the framing portion via the connecting portion, wherein
the extraction electrode contacts the inner peripheral side and the outer peripheral side of the framing portion, the extraction electrode including an end side that connects the inner peripheral side and the outer peripheral side of the extraction electrode, all of the end side being longer than the predetermined width.

2. The piezoelectric vibrating piece according to claim 1, wherein
the end side includes at least one of a plurality of straight lines, a curved line, and a straight line having an angle with respect to the long side and the short side.

3. The piezoelectric vibrating piece according to claim 2, wherein
the end side is formed in an L shape, a fan shape, a comb shape, or a shape in combination of the L shape, the fan shape and the comb shape shapes.

4. The piezoelectric vibrating piece according to claim 1, wherein
the extraction electrode includes a first metal layer and a second metal layer formed on a surface of the first metal layer, and
the first metal layer is made of chromium (Cr), chromium (Cr) and nickel (Ni), or chromium (Cr) and nickel tungsten (NiW).

5. A piezoelectric device, comprising:
the piezoelectric vibrating piece according to claim 1;
a base plate, being bonded on one principal surface of the framing portion;
a lid plate, being bonded on another principal surface of the framing portion to seal the vibrator; and
a non-conductive bonding material that bonds the piezoelectric vibrating piece and the base plate and bonds the piezoelectric vibrating piece and the lid plate, wherein
the end side contacts the bonding material as viewed from the outer peripheral side.
